(19) United States
(12) Patent Application Publication
(10) Pub. No.: US 2009/0242883 A1
(43) Pub. Date: Oct. 1, 2009

(54) Thin film transistor, active array substrate and method for manufacturing the same

(75) Inventors: Han-Tu Lin, Hsin-Chu (TW); Chih-Chun Yang, Hsin-Chu (TW); Chin-Yueh Liao, Hsin-Chu (TW); Chien-Hung Chen, Hsin-Chu (TW)

Correspondence Address: BACON & THOMAS, PLLC, 625 SLATERS LANE, FOURTH FLOOR, ALEXANDRIA, VA, 22314-1176, US

(73) Assignee: AU OPTRONICS CORP., Hsin-Chu (TW)

(21) Appl. No.: 12/149,858

(22) Filed: May 9, 2008

(30) Foreign Application Priority Data
Mar. 27, 2008 (TW) 97111107

(51) Int. Cl. H01L 33/00; H01L 21/00

(52) U.S. Cl. 257/59; 438/30; 257/E21.001; 257/E33.001

(57) ABSTRACT

A thin film transistor, an active array substrate having the same and methods for manufacturing the same are provided. The thin film transistor includes a base having a concave; a gate disposed in the concave; a gate insulator covering the gate and a portion of the gate insulator is in the concave; a channel layer disposed on the gate insulator; and a source and a drain are disposed on the channel layer and located in response to two sides of the gate.

This application claims the benefit of Taiwan Patent Application Serial No. 97111107, filed Mar. 27, 2008, the subject matter of which is incorporated herein by reference.

### BACKGROUND OF THE INVENTION

1. Field of the Invention

The present invention generally relates to a method for manufacturing an active array substrate, and especially relates to a method for manufacturing an active array substrate with a structure of conductive line embedded in a base.

2. Description of Related Art

Liquid crystal displays are commonly used because of thin, short and low radiation. Conventional liquid crystal display includes two substrates and a liquid crystal layer disposed therebetween. A sealant is located between the substrates for combining the two substrates and sealing the liquid crystal layer. The two substrates are active array substrate and color filter substrate, respectively.

Active array substrate comprises thin film transistors arranged in array and pixel electrodes each corresponding to each thin film transistor, respectively. Thin film transistor is used for a switch of the liquid crystal display unit. Besides, the way to control each of the pixel units of the liquid crystal display is selecting specific pixel by the scan line and the data line and providing proper operation voltage, then display image of the pixel will be created.

If the size of the thin film transistor liquid crystal display becomes large, problems of RC delay will be serious. Therefore, researches of conductive lines with low resist become popular, and develop of using copper lines is one of which. However, there are issues in the process if using copper conductive lines, for example: (1) attachment problems between copper and glass substrate; (2) copper residue or unexpected taper occurred while etching copper materials; (3) copper might be damaged by photoresist solution while conducting removing photoresist materials on the copper materials; and (4) expansion problems of copper, such as copper might expand in vertical direction to pierce other layers, or expand in horizontal direction to create other undesired patterns, etc.

Besides, how to thinner the thin film transistor liquid crystal display is another trend.

### SUMMARY OF THE INVENTION

Accordingly, the present invention is directed to provide a thin film transistor, which comprises a gate, attachment between the gate and the base being better, wherein the base has a concave for receive the gate.

The present invention is also directed to provide a thin film transistor. The thin film transistor comprises a source and a drain. The source and the drain are comprised of copper, molybdenum, titanium, chromium, silver, aluminium or the combinations thereof. A passication layer on the source/drain has an opening so that discontinuous conductive layer is connected with the source/drain. The conductive layer is comprised of copper, silver, aluminium or the combinations thereof.

The present invention is also directed to provide a thin film transistor. The thin film transistor comprises a base having a concave; a gate disposed in the concave; a gate insulator disposed on the gate, wherein at least one portion of the gate insulator is in the concave; a channel layer disposed on the gate insulator; and a source and a drain disposed on and corresponding to two sides of the channel layer.

The present invention is also directed to provide an active array substrate comprising said thin film transistor shown above.

The present invention is also directed to provide a method for manufacturing a thin film transistor. The method comprises providing a base; forming a patterned photoresist layer on the base, the patterned photoresist having an opening; etching the base to form a concave by using the patterned photoresist layer as a mask; forming a conductive material layer covering the patterned photoresist layer and the base; removing a portion of the conductive material layer directly on the patterned photoresist layer; removing the patterned photoresist layer; forming a gate in the concave; forming a gate insulator on the gate, wherein at least one portion of the gate insulator is in the concave; forming a channel layer on the gate insulator; and forming a source and a drain on and corresponding to two sides of the channel layer.

The present invention is also directed to provide a method for manufacturing an active array substrate. The method comprises providing a base; forming a patterned photoresist layer on the base; forming a patterned photoresist layer on the base, the patterned photoresist having an opening; etching the base to form a concave by using the patterned photoresist layer as a mask; forming a conductive material layer covering the patterned photoresist layer and the base; removing a portion of the conductive material layer directly on the patterned photoresist layer; removing the patterned photoresist layer; forming at least one scan line in the concave; forming at least one data line perpendicular to the scan line; forming at least one thin film transistor electrically connected with corresponding scan line and data line, wherein the thin film transistor comprises a gate insulator a portion of which is in the concave; and forming at least one pixel electrode electrically connected with the thin film transistor.

An objective of the present invention is to provide a thin film transistor having thinner structure.

An objective of the present invention is to provide a thin film transistor. Attachment between the gate of the thin film transistor and the base is better.

An objective of the present invention is to provide a thin film transistor. The drain of the thin film transistor has a multiple player. The drain does not pierce to the doped semiconductive layer or the channel layer.

An objective of the present invention is to provide a method for manufacturing a thin film transistor, to prevent problems of that photoresist solution damages gate or source/drain while conducting removing photoresist.

An objective of the present invention is to provide a method for manufacturing an active array substrate, to prevent problems of that photoresist solution damages gate, pad electrode, connection electrode, scan line, source/drain and/or data line while conducting removing photoresist.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A, 2A, 3A, 4A, 5A, 6A, 7A, 8A, 9A, 10A and 11A are corresponding top views of the method for manufacturing an active array substrate according to one embodiment of the present invention.

FIGS. 1B and 1C are cross section view along lines I-I′ and II-II′ of FIG. 1A respectively.

FIGS. 2B and 2C are cross section view along lines I-I′ and II-II′ of FIG. 2A respectively.

FIGS. 3B and 3C are cross section view along lines I-I′ and II-II′ of FIG. 3A respectively.

FIGS. 4B and 4C are cross section view along lines I-I′ and II-II′ of FIG. 4A respectively.

FIGS. 5B and 5C are cross section view along lines I-I′ and II-II′ of FIG. 5A respectively.

FIGS. 6B and 6C are cross section view along lines I-I′ and II-II′ of FIG. 6A respectively.

FIGS. 7B, 7C and 7D are cross section view along lines I-I′, II-II′ and III-III′ of FIG. 7A respectively.

FIGS. 8B, 8C and 8D are cross section view along lines I-I′, II-II′ and III-III′ of FIG. 8A respectively.

FIGS. 9B, 9C and 9D are cross section view along lines I-I′, II-II′ and III-III′ of FIG. 9A respectively.

FIGS. 10B, 10C and 10D are cross section view along lines I-I′, II-II′ and III-III′ of FIG. 10A respectively.

FIGS. 11B, 11C and 11D are cross section view along lines I-I′, II-II′ and III-III′ of FIG. 11A respectively.

FIG. 12 is liquid crystal display according to the embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

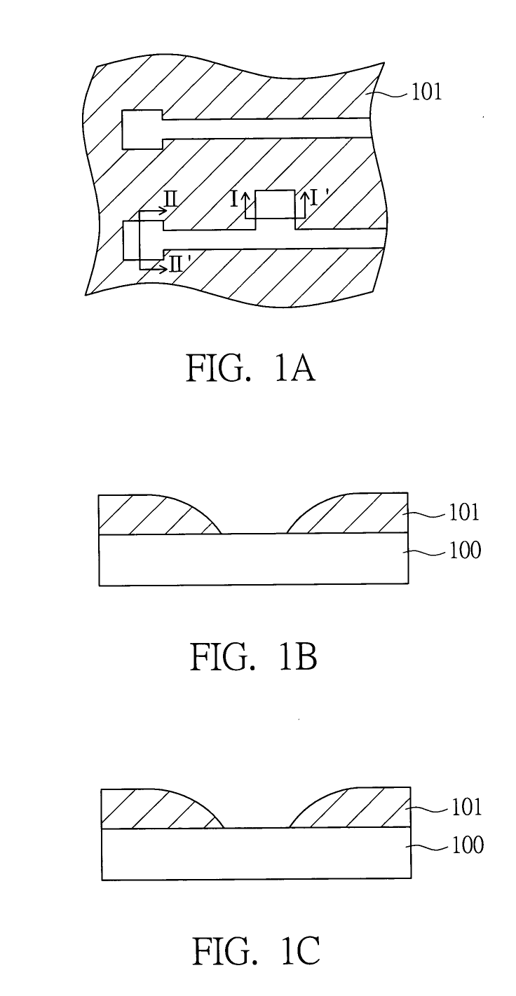

FIGS. 1A, 2A, 3A, 4A, 5A, 6A, 7A, 8A, 9A, 10A and 11A are corresponding top views of the method for manufacturing an active array substrate according to one embodiment of the present invention. For convenience and explanation, top views thereof are selectively observed in a perspective way.

As shown in FIG. 1A to 1C, FIGS. 1B and 1C are cross section view along lines I-I′ and II-II′ of FIG. 1A respectively. Particularly, where line I-I′ locates presents where thin film transistor is while manufacturing an active array substrate. In FIGS. 1B an 1C, first, provide base 100 and forming patterned photoresist layer 101 on the base 100.

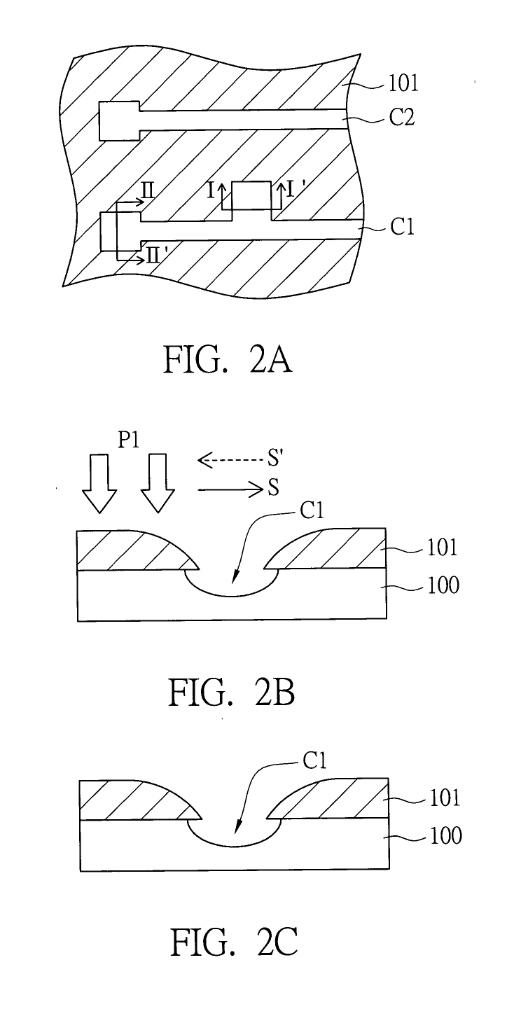

As shown in FIGS. 2A to 2C, FIGS. 2B and 2C are cross section view along lines I-I′ and II-II′ of FIG. 2A respectively. Etch the base 100 to form concave(s) C1 and C2 by using the patterned photoresist layer 101 as a mask. Concave C1 is responsive to subsequent formed gate, data lines and pad electrodes. Concave C2 is responsive to subsequent formed common lines. The step of etching the base 100 to form the concaves C1 and C2 comprises applying a dry etching process or a wet etching process. In the present embodiment, the dry etching process comprises an atmospheric plasma etching process P1 conducted to scan the base 100 for etching along direction s or direction s′ which is reverse of direction s. Advantages of using atmospheric plasma etching process are low cost and easy. However, the etching process types or scan directions used to etch the base 100 to form the concaves C1 and C2 are not limited in the present application. Concaves C1 and C2 have deepness of about 2000 angstroms to about 7000 angstroms, for example. The patterned photoresist layer 101 has a bottom surface in a shape of an under-cut corresponding to the concaves C1 or C2.

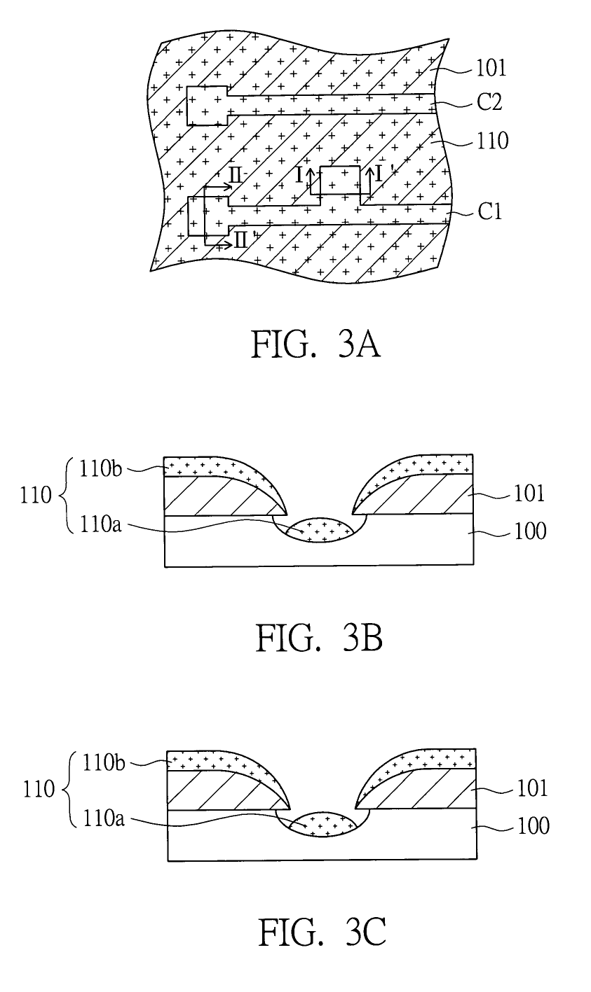

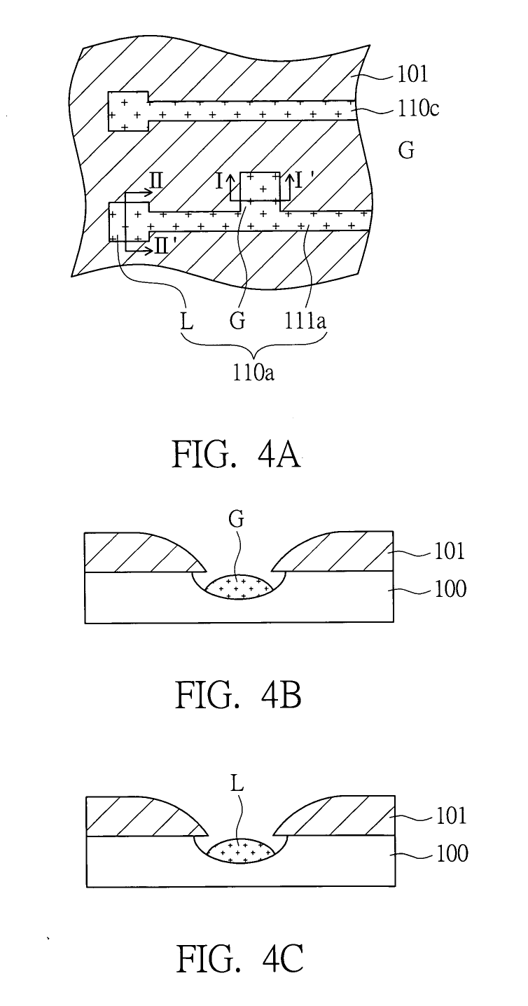

As shown in FIGS. 3A to 3C, FIGS. 3B and 3C are cross section view along lines I-I′ and II-II′ of FIG. 3A respectively. Form a conductive material layer 110 covering the patterned photoresist layer 101 and the base 100. The conductive material layer 110 is comprised of copper, silver, aluminium or the combinations thereof. Therefore, discontinuous conductive material layer 110 would be formed in responsive to patterned photoresist layer 101 and concaves C1 and C2. In FIGS. 3B and 3C, concave C1 receives at least one portion of the conductive material layer 110a. Conductive material layer 110b is formed on the patterned photoresist layer 101. Concave C2 receives at least one portion of the conductive material layer 110c (in FIG. 4A). However, numbers of layers of the conductive material layer 110 are not limited, for example, conductive material layer 110, which is composed of two or three layers, comprises a first layer formed on the base 100 and a second layer formed on the first layer and/or a third layer formed on the second layer. The first layer and/or the third layer may, for example, be comprised of copper, molybdenum, titanium, chromium, or the combinations thereof. The second layer may, for example, be comprised of copper, silver, aluminium or the combinations thereof.

As shown FIGS. 4A to 4C, FIGS. 4B and 4C are cross section view along lines I-I′ and II-II′ of FIG. 4A respectively. Remove at lease one portion of the conductive material layer 110b located on the patterned photoresist layer 101. The step of removing the at lease one portion of the conductive material layer 110b comprises applying a gas-solid shooting process. Advantages of using a gas-solid shooting process are omitting conventional wet etching process for conductive lines. Furthermore, because of the concaves C1 and C2, no or few residues of conductive material would occur in non-conductive lines areas.

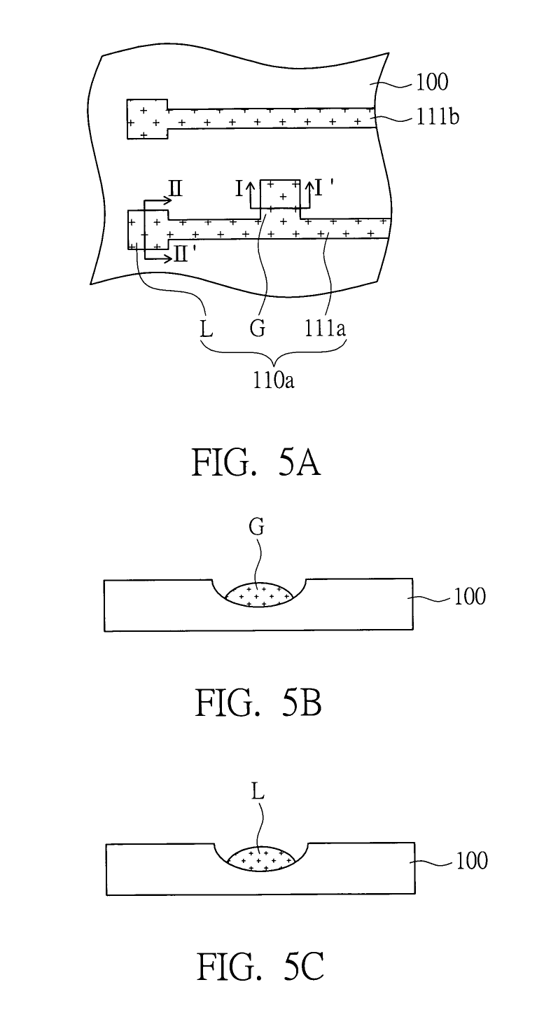

As shown in FIGS. 5A to 5C, FIGS. 5B and 5C are cross section view along lines I-I′ and II-II′ of FIG. 5A respectively. Remove the patterned photoresist layer 101. As a result, gate G, scan lines 111a, pad electrodes L and common lines 111b are formed. For example, gate G, scan lines 111a, pad electrodes L and common lines 111b are formed simultaneously. Gate G, scan lines 111a, pad electrodes L and/or common lines 111b has a top surface in a shape of a curve. Because gate G, scan lines 111a, pad electrodes L and common lines 111b are formed in the concaves C1 and C2, while removing patterned photoresist layer 101 by using photoresist solutions, gate G, scan lines 111a, pad electrodes L and common lines 111b would be difficultly damaged thereby. In FIG. 5A, base 100 is exposed outside the areas where the gate G, scan lines 111a, pad electrodes L and common lines 111b are.

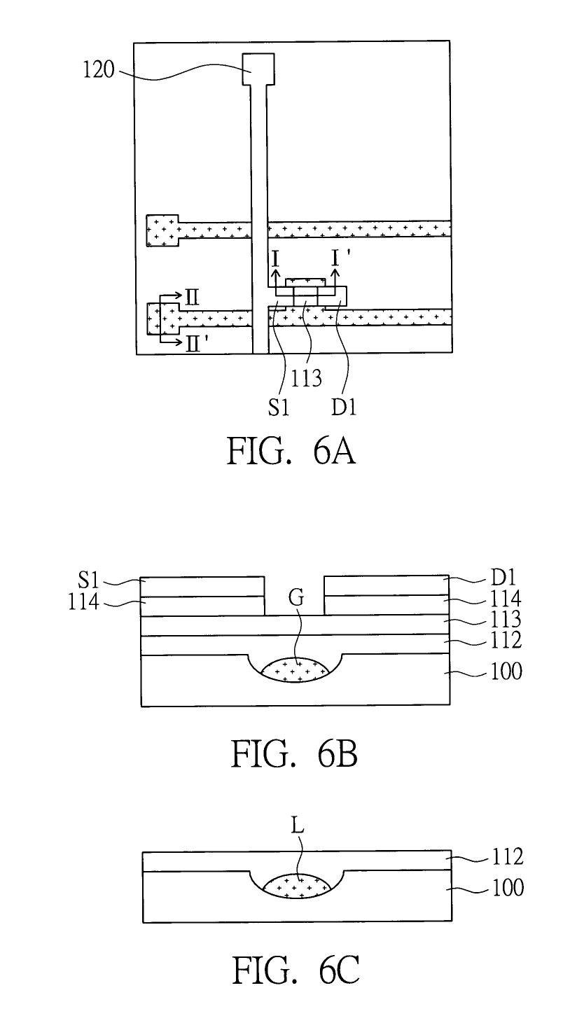

As shown in FIGS. 6A to 6C, FIGS. 6B and 6C are cross section view along lines I-I′ and II-II′ of FIG. 6A respectively. Form gate insulator 112 on the gate G, scan lines 111a, pad electrodes L, common lines 111b and the base 100. At least one portion of the gate insulator 112 is in the concaves C1 and C2. Then, form channel layer 113 on the gate insulator 112 in accordance with the thin film transistor. The channel layer 113 may, for example, be comprised of semiconductive material, such as amorphous silicon or polysilicon. Thereafter, selectively form doped semiconductive layer 114 in accordance with two sides of the gate G. Form source layer S1 and drain layer D1 on the doped semiconductive layer 114. The source layer S1 and drain layer D1 locate on the channel layer 113 and in accordance with the two sides of the gate G, respectively. Simultaneously, form data lines 120 and data line pad electrodes (not shown). The source layer S1, drain layer D1 and data lines 120 may, for example, be comprised of copper, molybdenum, titanium, chromium, silver, aluminium or the combinations thereof. As a result, thin film transistor is secussively formed. The gate G is connected with corresponding scan line 111a. The source layer S1 is connected with corresponding data line 120.

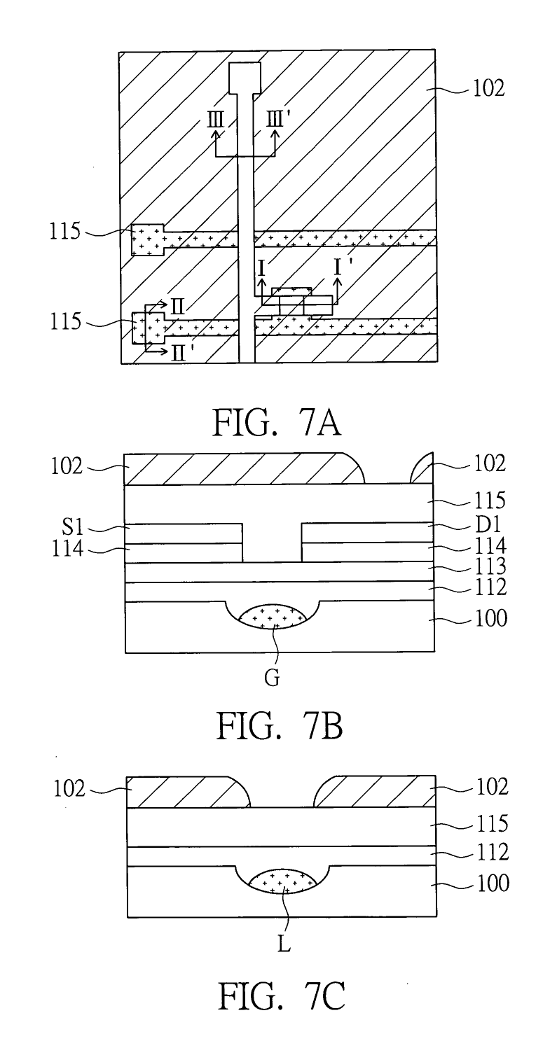

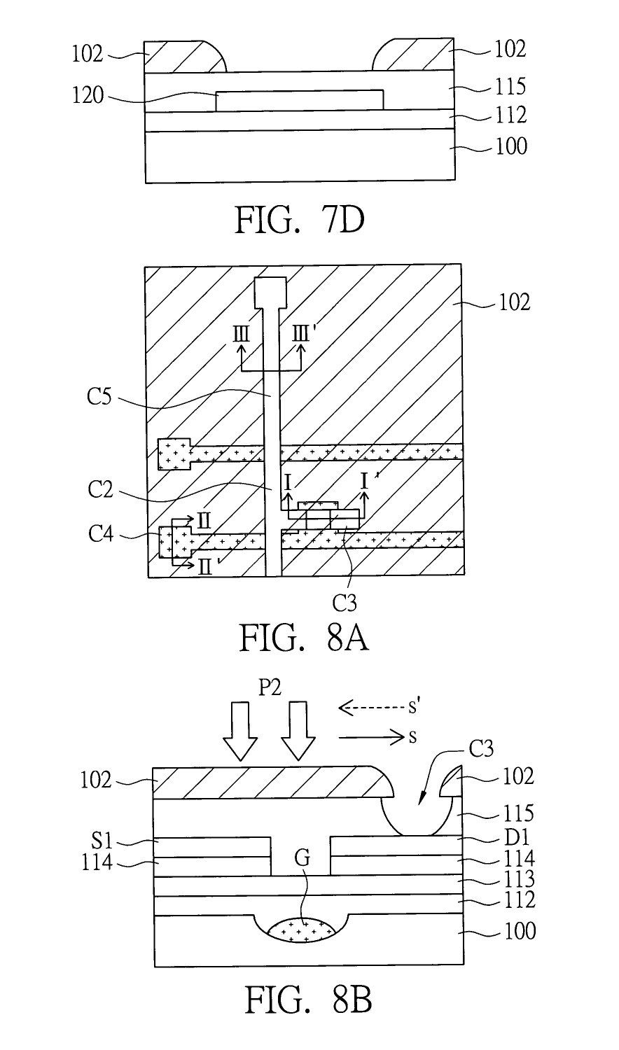

As shown in FIGS. 7A to 7D, FIGS. 7B, 7C and 7D are cross section view along lines I-I′, II-II′ and III-III′ of FIG. 7A respectively. Form passivation layer 115 covering the data lines 120, source layer S1, drain layer D1 and gate insulator 112. Form patterned photoresist layer 102 on the passivation layer 115. In FIGS. 7B to 7D in order, patterned photoresist layer 102 has a plurality of openings in responsive to subsequent formed contact hole C3 and pixel electrode 140, contact hole C4 directly over the pad electrode L and contact hole C5 directly over the data line 120 to expose at least one portion of the passivation layer 115.

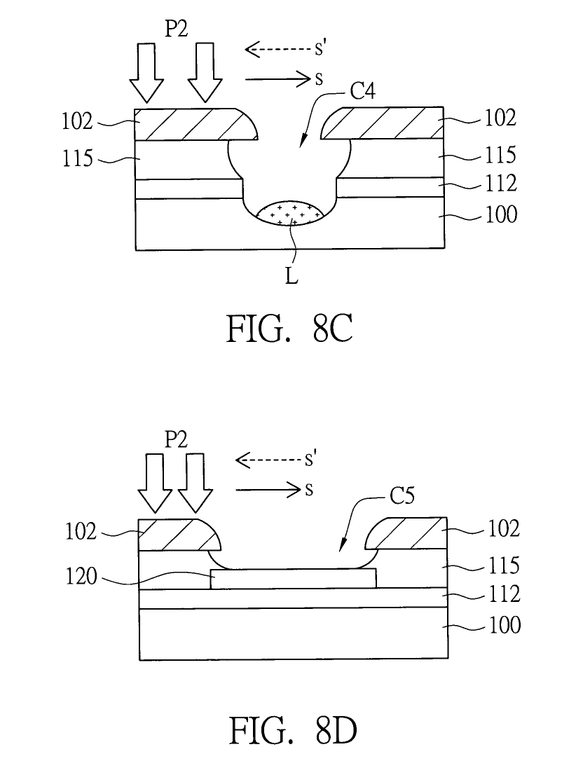

As shown in FIGS. 8A to 8D, FIGS. 8B, 8C and 8D are cross section view along lines I-I′, II-II′ and III-III′ of FIG. 8A respectively. Using the concepts of forming the concaves C1 and C2 similar to the mentioned above, to etch the passivation layer 115 to form contact holes C3 and C5 to expose drain layer D1 and data line 120 respectively by using the patterned photoresist layer 102 as a mask. Etch the passivation layer 115 and the gate insulator 112 to form the contact hole C4 to expose the pad electrode L. The steps of forming the contact holes C3, C4 and C5 may, for example, comprise applying a wet etching process or a dry etching process. In the present embodiment, the dry etching process comprises an atmospheric plasma etching process P2 conducted to scan for etching along direction s or direction s′ which is reverse of direction s. Advantages of using atmospheric plasma etching process are low cost and easy. However, the etching process types or scan directions used are not limited in the present application. The patterned photoresist layer 102 has a bottom surface in a shape of an under-cut corresponding to the contact holes C3, C4 and C5.

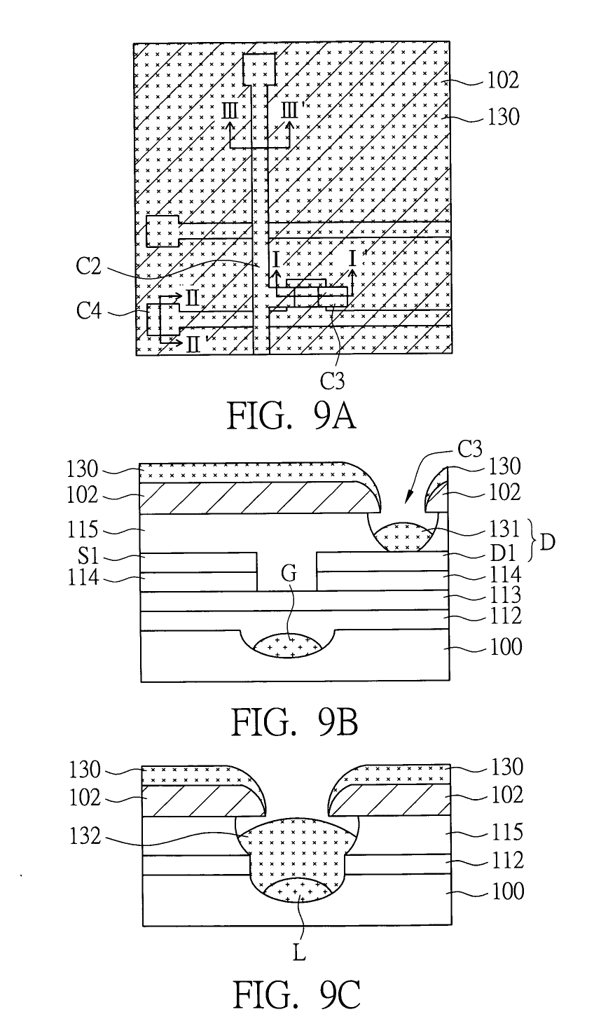

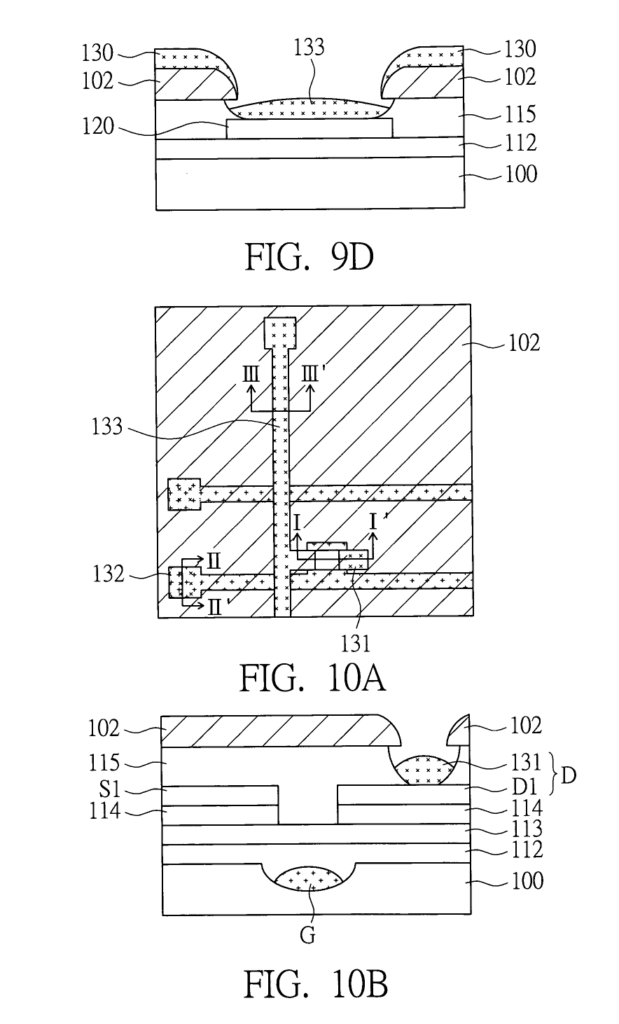

As shown in FIGS. 9A to 9D, FIGS. 9B, 9C and 9D are cross section view along lines I-I′, II-II′ and III-III′ of FIG. 9A respectively. Form conductive material layer 130 covering the patterned photoresist layer 102, drain layer D1, pad electrodes L and data lines 120. Herein, drain layer D1 and conductive layer 131 directly on the drain layer D1 are defined into drain D of the thin film transistor. Conductive material layer directly on the pad electrode L is connection electrode 132. Conductive material layer directly on the data lines 120 is conductive later 133. The conductive material layer 130 may, for example, be comprised of copper, silver, aluminium or the combinations thereof. Selectively, conductive material layer may be further formed on the source layer S1 to form a multi-layer source S. However, conductive material layer 130 may be multi-layer structure. For example, sequentially form a first layer and a second layer. The first layer may, for example, be comprised of copper, silver, aluminium or the combinations thereof. The second layer may, for example, be comprised of copper, molybdenum, titanium, chromium, silver, aluminium or the combinations thereof. Because source layer S1 or drain layer D1 is formed between the conductive material layer 130 and the doped semiconductive layer 114 (or the channel layer 113), problems or possibility of that conductive material layer 130 pierces down to the doped semiconductive layer 114 (or the channel layer 113) can be prevented or lowered.

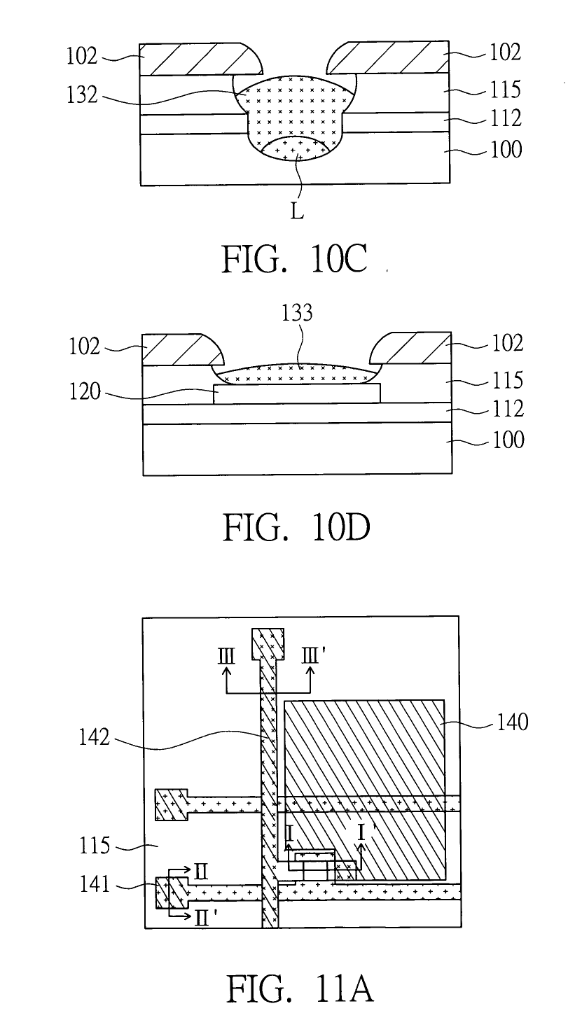

As shown in FIGS. 10A to 10D, FIGS. 10B, 10C and 10D are cross section view along lines I-I′, II-II′ and III-III′ of FIG. 10A respectively. Remove the conductive material layer 130 on the patterned photoresist layer 102. In the present embodiment, the step of removing the conductive material layer 130 on the patterned photoresist layer 102 comprises applying a gas-solid shooting process. Advantages of using a gas-solid shooting process are omitting conventional wet etching process for conductive lines. Furthermore, because of the contact holes C3, C4 and C5, no or few residues of conductive material would occur in non-conductive lines areas.

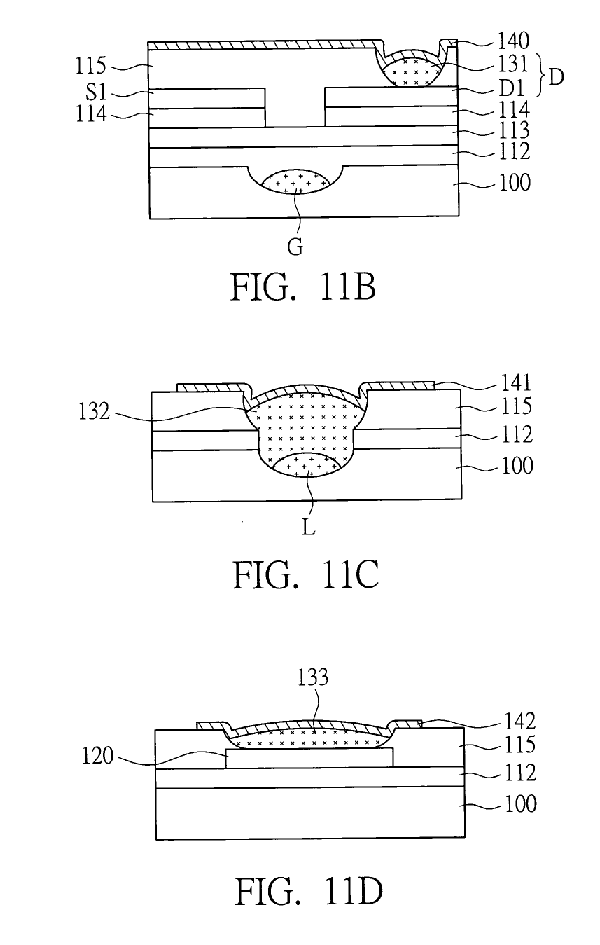

As shown in FIGS. 11A to 11D, FIGS. 11B, 11C and 11D are cross section view along lines I-I′, II-II′ and III-III′ of FIG. 11A respectively. After removing patterned photoresist layer 102 by using photoresist solutions, in FIGS. 11B, 11C and 11D, pixel electrode 140, protective electrode 141 and 142 are formed. The step of forming the pixel electrode 140, protective electrode 141 and 142 comprises, for example, forming a transparent conductive layer covering thereon and conducting photoresist-exposure-etching processes. The transparent conductive layer may, for example, be comprised of ITO, IZO, ITZO or the combinations thereof. Pixel electrode 140 and drain D are electrically connected via contact hole C3. Protective electrodes 141 and 142 are on the connection electrode 132 and the conductive layer 133, respectively.

As a result, an active array substrate 10 is formed successively. Because the active array substrate 10 has concaves C1 and C2 to receive conductive lines, thinner active array substrate 10 can be created. Besides, problem or possibility of that the conductive material residue may be shown in non-conductive lines areas can be prevented or lowered.

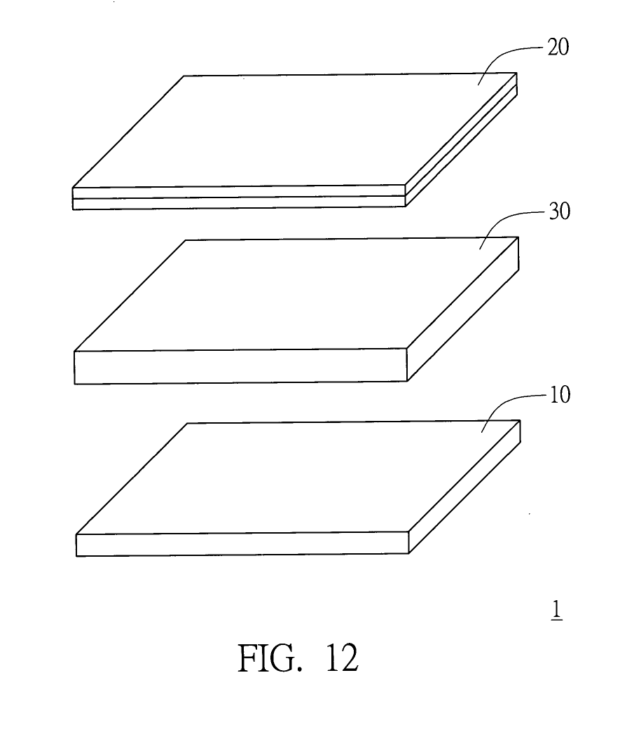

In FIG. 12, liquid crystal display 1 comprises said active array substrate 10, opposite substrate 20 and liquid crystal layer 30 sealed therebetween. The opposite substrate 20 may, for example, be a color filter substrate.

However, as the method for manufacturing an active array substrate 10, person in the skilled art may conduct some conventional steps before the step of forming the gate insulator 112 shown above. In other words, do not form concaves C1 and C2, and only using steps after the step of forming the gate insulator 112 (corresponding to FIGS. 6A to 11D and description thereof incorporated with necessary conventional steps which are before the step thereof, to form an active array substrate.

On the other hand, person in the skilled art may conduct some conventional steps after the step of forming the gate insulator 112 shown above. In other words, keep the steps for forming concaves C1 and C2, and only using steps before the step of forming the gate insulator 112 (corresponding to FIGS. 1A to 5C and description thereof) incorporated with necessary conventional steps which are after the step thereof, to form an active array substrate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a base having a concave;
a gate disposed in the concave;
a gate insulator disposed on the gate, wherein at least one portion of the gate insulator is in the concave;
a channel layer disposed on the gate insulator; and
a source and a drain disposed on and corresponding to two sides of the channel layer.

2. The thin film transistor according to claim 1, wherein:
the gate has a top surface in a shape of a curve;
the gate is comprised of copper, silver, aluminium or the combinations thereof;
the source and the drain are comprised of copper, molybdenum, titanium, chromium, silver, aluminium or the combinations thereof; and
the concave has a deepness of about 2000 angstroms to about 7000 angstroms.

3. The thin film transistor according to claim 1, wherein the gate comprises:
a first layer disposed on the base, wherein the first layer is comprised of copper, molybdenum, titanium, chromium, or the combinations thereof; and
a second layer disposed on the first layer, wherein the second layer is comprised of copper, silver, aluminium or the combinations thereof.

4. The thin film transistor according to claim 3, wherein the gate further comprises a third layer disposed on the second layer, wherein the third layer is comprised of copper, molybdenum, titanium, chromium, or the combinations thereof.

5. An active array substrate, comprising:
a base having a concave;
at least one scan line disposed on the base;
at least one data line, perpendicular to the at least one scan line;
at least one thin film transistor electrically connected with corresponding scan line and data line, wherein the at least one thin film transistor comprises:
a gate disposed in the concave;
a gate insulator disposed on the gate, wherein at least one portion of the gate insulator is in the concave;
a channel layer disposed on the gate insulator; and
a source and a drain disposed on and corresponding to two sides of the channel layer, wherein the source and the drain are comprised of copper, molybdenum, titanium, chromium, silver, aluminium or the combinations thereof; and
at least one pixel electrode electrically connected with the thin film transistor.

6. The active array substrate according to claim 5, wherein:
the gate has a top surface in a shape of a curve;
the concave has a deepness of about 2000 angstroms to about 7000 angstroms; and
the at least one scan line is comprised of copper, silver, aluminium or the combinations thereof.

7. The active array substrate according to claim 5, wherein the at least one scan line is further disposed in the concave, and the at least one scan line comprises:
a first layer disposed on the base, wherein the first layer is comprised of copper, molybdenum, titanium, chromium, or the combinations thereof; and
a second layer disposed on the first layer, wherein the second layer is comprised of copper, silver, aluminium or the combinations thereof.

8. The active array substrate according to claim 7, wherein the scan line further comprises a third layer disposed on the second layer, wherein the third layer is comprised of copper, molybdenum, titanium, chromium, or the combinations thereof.

9. The active array substrate according to claim 5, wherein the base further has an another concave, and the active array substrate further comprises a common line disposed in the another concave.

10. The active array substrate according to claim 5, further comprising:
a pad electrode disposed in the concave and electrically connected with the scan line;
a connection electrode disposed on the lad electrode; and a protective electrode disposed on the connection electrode.

11. The active array substrate according to claim 5, further comprising:
a passivation layer disposed on the data line, wherein the passivation layer has an opening to expose the data line; and
a conductive layer disposed on the passivation layer and electrically connected with the data line via the opening, wherein the conductive layer is comprised of copper, silver, aluminium, or the combinations thereof.

12. An active array substrate, comprising:
a base;
at least one scan line disposed on the base;
at least one data line, perpendicular to the at least one scan line;
a passivation layer disposed on the data line, wherein the passivation has an opening to expose the data line;
a conductive layer disposed on the passivation layer and electrically connected with the data line via the opening;
at least one thin film transistor electrically connected with corresponding scan line and data line; and
at least one pixel electrode electrically connected with the thin film transistor.

13. An active array substrate, comprising:
a base having at least one concave;
at least one scan line disposed on the base;
at least one data line, perpendicular to the at least one scan line;
at least one thin film transistor electrically connected with corresponding scan line and data line;
at least one pixel electrode electrically connected with the thin film transistor; and
a pad electrode disposed in the concave.

14. The active array substrate according to claim 13, further comprising a gate insulator disposed on the pad electrode, wherein at least one portion of the gate insulator is disposed in the concave.

15. The active array substrate according to claim 1, wherein the pad electrode has a top surface in a shape of a curve.

16. A method for manufacturing a thin film transistor, comprising:
providing a base, wherein the base has a concave;
forming a gate in the concave;
forming a gate insulator on the gate, wherein at least one portion of the gate insulator is in the concave;
forming a channel layer on the gate insulator; and
forming a source and a drain on and corresponding to two sides of the channel layer.

17. The method according to claim 16, further comprising forming a doped semiconductive layer between the source/drain and the channel layer.

18. The method according to claim 16, before the step of the forming the gate, further comprising:
forming a patterned photoresist layer on the base, wherein the patterned photoresist layer has an opening;
etching the base to form the concave by using the patterned photoresist layer as a mask;
forming a conductive material layer to cover patterned photoresist layer and the base;
removing a portion of the conductive material layer directly on the patterned photoresist layer; and
removing the patterned photoresist layer.

19. The method according to claim 18, wherein the step of etching the base to form the concave comprises applying a dry etching process or a wet etching process, and wherein the dry etching process comprises an atmospheric plasma etching process.

20. The method according to claim 18, wherein the step of removing the portion of the conductive material layer directly on the patterned photoresist layer comprises applying a gas-solid shooting process.

21. The method according to claim 16, wherein:
the gate has a top surface in a shape of a curve;
the gate is comprised of copper, silver, aluminium or the combinations thereof;
the concave has a deepness of about 2000 angstroms to about 7000 angstroms; and
the patterned photoresist layer has a bottom surface in a shape of an under-cut corresponding to the concave.

22. A method for manufacturing an active array substrate, comprising:
providing a base, wherein the base has a concave;
forming at least one scan line in the concave;
forming at least one data line perpendicular to the at least one scan line;
forming at lease one thin film transistor electrically connected with corresponding scan line and data line, wherein the thin film transistor comprises a gate insulator, and wherein at least one portion of the gate insulator is in the concave; and
forming at least one pixel electrode electrically connected with the thin film transistor.

23. The method according to claim 22, wherein the base further has an another concave, the method further comprising forming a common line in the another concave.

24. The method according to claim 22, further comprising:
forming a pad electrode in the concave, wherein the pad electrode is electrically connected with corresponding scan line;
forming a connection electrode on the pad electrode; and
forming a protective electrode on the connection electrode, wherein the protective electrode and the pixel electrode are formed simultaneously.

25. The method according to claim 22, before the step of forming the at least one scan line, further comprising:
forming a patterned photoresist layer on the base;
etching the base to form the concave by using the patterned photoresist layer as a mask, wherein patterned photoresist layer has a bottom surface in a shape of an under-cut corresponding to the concave;
forming a conductive material layer to cover patterned photoresist layer and the base;
removing a portion of the conductive material layer directly on the patterned photoresist layer; and
removing the patterned photoresist layer.

26. The method according to claim 25, wherein the step of etching the base to form the concave comprises applying a dry etching process or a wet etching process, wherein the dry etching process comprises an atmospheric plasma etching process, and wherein the step of removing the portion of the conductive material layer directly on the patterned photoresist layer comprises applying a gas-solid shooting process.

27. The method according to claim 22, further comprising:
forming a passivation layer on the data line;
forming a patterned photoresist layer on the passivation layer;
etching the passivation layer to form an opening to expose the data line by using the patterned photoresist layer as a mask;
forming a conductive material layer on the patterned photoresist layer to electrically connected with the data line via the opening;
removing a portion of the conductive material layer on the patterned photoresist layer to form a conductive payer on the data line; and
removing the patterned photoresist layer.

28. The method according to claim 27, wherein the step of etching the assivation layer to form the opening comprises applying an atmospheric plasma etching process, and wherein the the step of removing the portion of the conductive material layer on the patterned photoresist layer comprises applying a gas-solid shooting process.

29. The method according to claim 22, before the step of forming the pixel electrode, further comprising:
forming a passivation layer on the thin film transistor;
forming a patterned photoresist layer on the passivation layer;
etching the passivation layer to form a contact hole to expose a drain of the thin film transistor by using the patterned photoresist layer as a mask; and
removing the patterned photoresist layer.

30. The method according to claim 29, wherein the pixel electrode is electrically connected with the drain via the contact hole, and wherein the step of etching the passivation layer to form the contact hole comprises applying an atmospheric plasma etching process.
